(19) United States
(12) Patent Application Publication
(10) Pub. No.: US 2004/0061241 A1
(43) Pub. Date: Apr. 1, 2004

(54) Semiconductor device power interconnect striping

(76) Inventors: Edward P. Osburn, Tigard, OR (US); Erik W. Peter, Hillsboro, OR (US); Timothy M. Gates, Hillsboro, OR (US)

Correspondence Address: Michael J. Mallie, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/261,544

(22) Filed: Sep. 30, 2002

(51) Int. Cl. H01L 23/48; H01L 21/44

(52) U.S. Cl. 257/786; 438/612; 257/773; 438/666; 257/691; 361/777; 361/791

(57) ABSTRACT

A method and an apparatus for improving the delivery and filtering of power to a semiconductor device is disclosed by organizing out interconnects (pins, balls, pads or other interconnects) used to carry power in a striped configuration that shortens the conductive path required between a power source and a semiconductor device and that reduces the resistance of that conductive path.

### FIELD OF THE INVENTION

A method and an apparatus for improving the delivery and filtering of power to a semiconductor device is disclosed.

### ART BACKGROUND

As semiconductor devices, especially processors, have continued to increase in complexity and capability, they have also continued to require ever increasing amounts of power. Indeed, the amount of electrical current required in supplying power to such semiconductor devices has made it a commonplace practice to devote many of the pins, balls, pads or other types of interconnect (though it is common practice to use the term “pins” as engineering shorthand for the term “interconnect” regardless of whether the interconnects are truly pins or not) to ensure sufficient current capacity and adequate voltage.

FIG. 1 depicts a prior art pinout 100 for a semiconductor device. Specifically, FIG. 1 depicts the pinout used by Advanced Micro Devices of Sunnyvale, Calif. for a series of processors. As shown, Vss interconnects 150 and Vcc interconnects 160 are dispersed throughout pinout 100. FIG. 2 depicts a prior art pinout 200 for another semiconductor device. Specifically, FIG. 2 depicts the pinout used by Intel Corporation of Santa Clara, Calif. for a different series of processors. Somewhat like the case in pinout 100, Vss interconnects 250 and Vcc interconnects 260 are dispersed through pinout 200.

As can be seen in both FIGS. 1 and 2, a large proportion of the available interconnects have been devoted to supplying power. However, the dispersion of both Vss and Vcc interconnects throughout pinouts 100 and 200 does not permit the use of large uninterrupted traces to carry power across a printed circuit board (PCB) from a power source to the Vss or Vcc interconnects of either pinouts 100 or 200. Furthermore, this same dispersion of both Vss and Vcc interconnects also results in any ground or power plane used to supply Vss and/or Vcc being so riddled with holes as to become too discontiguous to carry a large current with only low resistance. As those skilled in the art of PCB design will recognize, the sheer number of interconnects in semiconductor device pinouts, such as pinouts 100 and 200, requires that the interconnects to be spaced closely together, which in turn requires that multiple layers of PCB traces be used to carry power and/or signals to and from these interconnects. This is the case regardless of whether a semiconductor device is attached to a PCB using current surfacemount or older through-hole approaches, because although the interconnects in surfacemount approaches don't penetrate through layers of a PCB, themselves, they require connections through vias that do.

With the use of either smaller traces or planes riddled with holes to supply power to semiconductor devices comes a corresponding increase in resistance, and this reduces the effectiveness of filtering capacitors placed adjacent to or in the middle of either pinouts 100 or 200. Transients caused by a semiconductor device and transmitted by one or more Vss and/or Vcc interconnects to a PCB are caused to last longer, have larger magnitudes, and not be as swiftly countered by filtering capacitors since these transients take longer than is often desirable to reach the filtering capacitors when propagating through traces and/or planes of such higher resistance. Furthermore, where a voltage regulator is used to supply power to a semiconductor device, these same traces and/or planes of such higher resistance result in changes in current requirements taking longer to be reflected at the output of even a voltage regulator located immediately adjacent to the semiconductor device, because the higher resistance does not allow the resulting change in voltage at the Vss and/or Vcc interconnects to propagate as quickly towards the output of the voltage regulator so that the voltage regulator may boost or lower its output as appropriate. Finally, the higher resistance results in more of the power meant for the semiconductor device to be lost as heat dissipated by the traces and/or planes.

### BRIEF DESCRIPTION OF THE DRAWINGS

The objects, features, and advantages of the invention as hereinafter claimed will be apparent to one skilled in the art in view of the following detailed description in which:

FIG. 1 depicts a prior art pinout.

FIG. 2 depicts another prior art pinout.

FIG. 3 depicts an embodiment of a pinout.

FIG. 4 depicts another embodiment of a pinout.

FIG. 5 depicts still another embodiment of a pinout.

FIG. 6 depicts yet another embodiment of a pinout.

FIGS. 7a and 7b depict an embodiment of a pinout and PCB traces for a semiconductor device using through-hole technology.

FIGS. 8a and 8b depict an embodiment of a pinout and PCB traces for a semiconductor device using surface mount technology.

### DETAILED DESCRIPTION

Although numerous details are set forth for purposes of explanation and to provide a thorough understanding in the following description, it will be apparent to those skilled in the art that these specific details are not required in order to practice embodiments of the invention as hereinafter claimed.

A method and apparatus for improving the conducting of power from a power source to a semiconductor device is disclosed. Specifically, a layout of interconnects (pins, balls, pads or other interconnects) is disclosed in which interconnects used to carry power are organized in a striped configuration that shortens the conductive path required between a power source and a semiconductor device and that reduces the resistance of that conductive path. Although the discussion is largely centered on semiconductor devices with packages in which pins are organized into a largely grid-like array, it will be understood by those skilled in the art that the invention as hereinafter claimed is applicable to a wide variety of electronic devices using a wide variety of configurations of packages. Also, although the term “pinout” is used to refer to the physical layout of interconnects of the package of a semiconductor device, this is only done in recognition of the common use of this term in industry, and is in no way meant to be construed as limiting the application of the teachings herein to semiconductor devices with packages on which actual pins are the particular type of interconnect used.

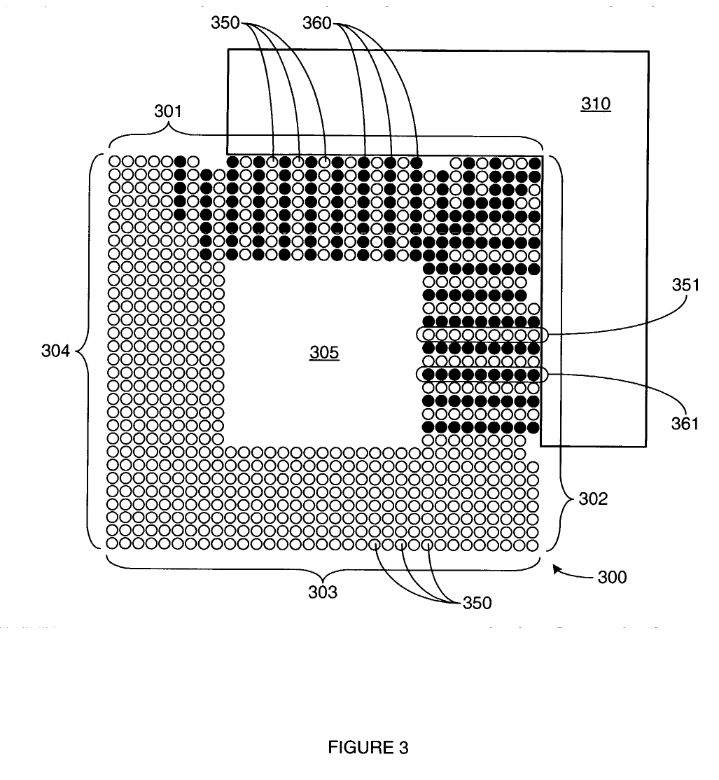

FIG. 3 depicts an embodiment with a pinout of a semiconductor device. The interconnects of pinout 300 are arranged in a two-dimensional grid pattern having four distinct sides, including sides 301 and 302, and unpopulated center 305. Along sides 301 and 302, Vss interconnects 350 and Vcc interconnects 360 are arranged in contiguous stripes of interconnects, such as Vss stripe 351 and Vcc stripe 361, most of which run in alternating parallel lines.

Pinout 300 may also have more of Vss interconnects 350 dispersed among the signal interconnects within sides 303 and 304. However, the use of differential signaling among the signal interconnects within sides 303 and 304 and/or other factors may allow the number of Vss interconnects 350 within sides 303 and/or 304 to be reduced in quantity from what is depicted in FIG. 3, or perhaps, eliminated altogether.

The stripes of Vss and Vcc interconnects, 350 and 360, such as Vss stripe 351 and Vcc stripe 361, permit traces and/or planes to provide larger pathways to carry current from a power source to the semiconductor device using pinout 300. In one embodiment, the stripes formed by Vss and Vcc interconnects, 350 and 360, as shown, are oriented in directions that would be advantageous for having a source of Vss and Vcc located along sides 301 and 302, such as at location 310. In alternate embodiments, the stripes formed by Vss and Vcc interconnects, 350 and 360, along sides 301 and 302 may be oriented in other directions, perhaps to accommodate the placement of a source of Vss and Vcc only at the corner formed by sides 301 and 302, or perhaps along only one of sides 301 or 302.

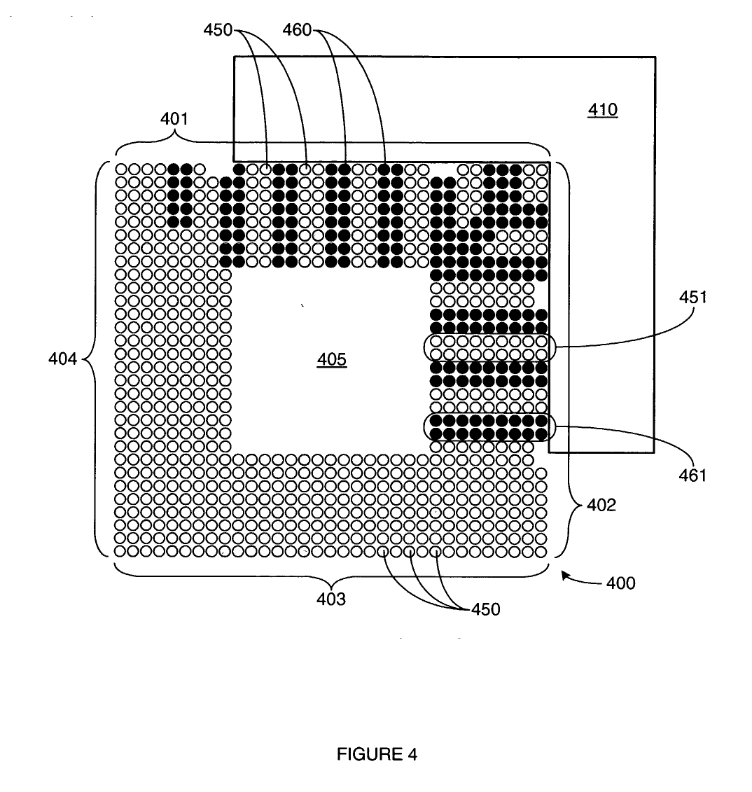

FIG. 4 depicts another embodiment with a pinout of a semiconductor device. As in pinout 300 of FIG. 3, the interconnects of pinout 400 are arranged in a two-dimensional grid pattern having four distinct sides, including sides 401 and 402, and unpopulated center 405. Along sides 401 and 402, Vss interconnects 450 and Vcc interconnects 460 are arranged in contiguous stripes of interconnects, such as Vss stripe 451 and Vcc stripe 461, most of which run in alternating parallel lines. Pinout 400 may also have more of Vss interconnects 450 dispersed among the signal interconnects within sides 403 and 404.

As was the case in pinout 300 of FIG. 3, the stripes of Vss interconnects 450 and Vcc interconnects 460 of pinout 400, such as Vss stripe 451 and Vcc stripe 461, make possible traces and/or planes that can provide larger pathways to carry more current from a power source to the semiconductor device. However, unlike the stripes of Vss interconnects 350 and Vcc interconnects 360 of pinout 300, most of the stripes of Vss interconnects 450 and Vcc interconnects 460 of pinout 400 are made up of double rows or columns of interconnects. These double-wide stripes of interconnects permit even larger traces to be used to carry current. Also, these double-wide stripes provide opportunities for planes being penetrated by fewer vias for Vss and/or Vcc, or for such vias to be arrayed in a manner that reduces the impact on the ability of planes to carry more current.

Although FIG. 3 depicts stripes made up of only single columns and/or rows of interconnects, and FIG. 4 depicts double-wide stripes, it will be understood by those skilled in the art that the teachings herein may be practiced with regard to yet wider stripes (e.g., triple-wide stripes, etc.). The choice of width of stripes, in some embodiments, may be based on aspects of the design of the circuitry and/or die of a semiconductor device having Vss interconnects and/or Vcc interconnects arrayed in stripes, or by aspects of the design of the package used for such a semiconductor device. Alternatively, in other embodiments, the choice of width of stripes may be based on aspects such as how inductive the particular type of interconnect used may be and/or the effect of the choice of interconnect on loop inductance between Vcc and Vss pins. Such aspects as are taken into account would have to be balanced with the differences in resistance that would arise for each possible stripe width.

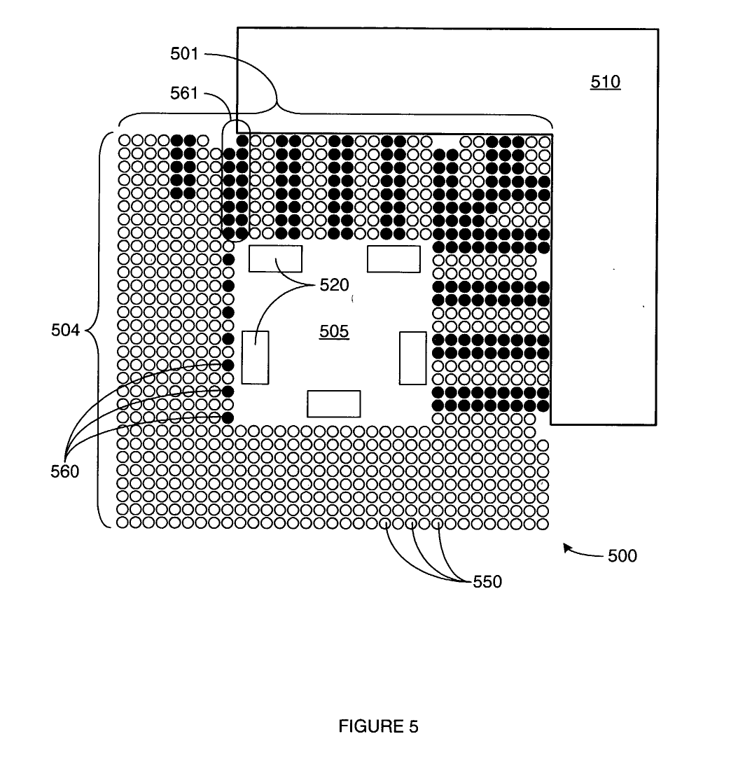

FIG. 5 depicts still another embodiment with a pinout of a semiconductor device. Pinout 500 is largely similar to pinout 400 of FIG. 4, including having stripes of Vss and Vcc interconnects oriented in directions advantageous for having a source of Vss and Vcc at location 510. The principal difference between pinout 400 and pinout 500 is that a number of additional Vss interconnects 560 have been placed within side 504 of pinout 500 along one edge of center location 505.

Within center location 505 are positioned a plurality of filtering components 520. Filtering components 520 could be capacitors and/or other varieties of components used to counter spikes, troughs and/or other forms of transients in Vss and/or Vcc conductors adjacent to the interconnects of pinout 500. These additional Vss interconnects 560 are provided along one edge of center location 505 within side 504 to enhance the effectiveness of filtering components 520 by providing a shorter conductive path between Vss within a semiconductor device using pinout 500 and at least one of filtering components 520. The location of these additional Vss interconnects 560 along side 504 permits the stripe formed by these additional Vss interconnects 560 to essentially extend Vss stripe 561 formed in side 501, thereby allowing at least a larger trace of conductive material on a PCB where pinout 500 is used to continue along the extended stripe to reduce the likelihood of differential voltages developing between Vss interconnects 560 along the extended stripe.

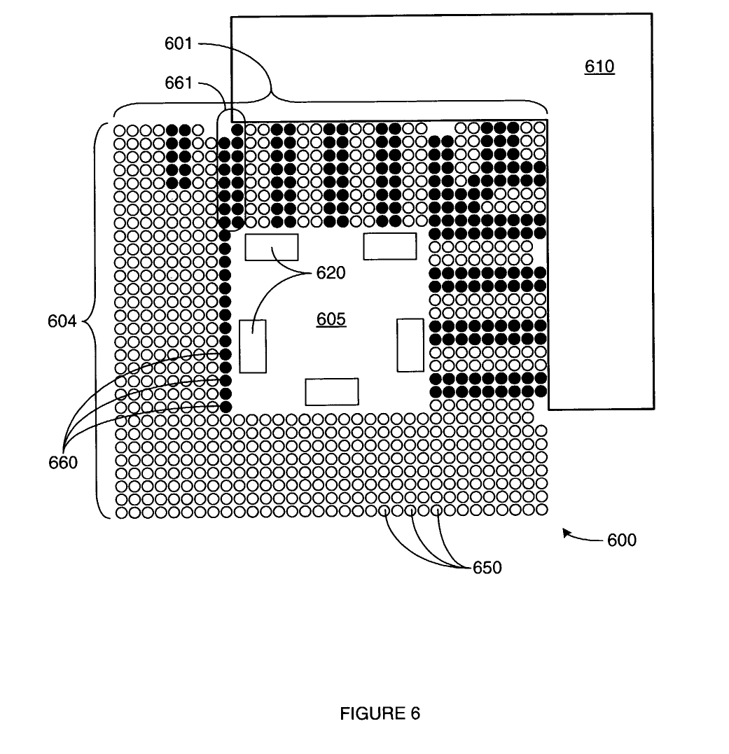

FIG. 6 depicts yet another embodiment with a pinout of a semiconductor device. Pinout 600 of FIG. 6 is largely similar to pinout 500 of FIG. 5, including having stripes of Vss and Vcc interconnects oriented in directions advantageous for having a source of Vss and Vcc at a particular location, such as location 610, as well as extending a stripe of Vss interconnects making up Vss stripe 661 within side 601 into side 604 along center location 605. The principal difference between pinout 500 and pinout 600 is that the extension of Vss stripe 661 is accomplished with Vss interconnects 660 forming a solid stripe.

As was the case with pinout 500, a plurality of filtering components 620 have been placed in center location 605. Filtering components 620 could be capacitors and/or other varieties of components used to counter spikes, troughs and/or other forms of transients in Vss and/or Vcc conductors adjacent to the interconnects of pinout 500. These additional Vss interconnects 660 are provided along one edge of center location 605 within side 604 to enhance the effectiveness of filtering components 620 by providing a shorter conductive path between Vss within a semiconductor device using pinout 600 and at least one of filtering components 620. As was the case with pinout 500, the extension of Vss stripe 661 allows at least a larger trace of conductive material on a PCB where pinout 600 is used to continue along the extended stripe which reduces the likelihood of differential voltages developing between Vss interconnects 660 along the extended stripe.

Referring to both FIGS. 5 and 6, the extension of Vss stripes 561 and 661 with Vss interconnects 560 and 660 become more effective in increasing the effectiveness of filtering components 520 and 620 if there are also Vcc interconnects within sides 504 and 604 such that shortened pathways are offered for both Vcc and Vss. As shown in the examples provided by pinouts 500 and 600 of FIGS. 5 and 6, some embodiments may have Vss interconnects are interspersed throughout sides 504 and 604. Alternatively, as is also shown in pinouts 500 and 600, other embodiments may have a stripe of Vss interconnects parallel to the stripe of Vcc interconnects in sides 504 and 604, possibly also extending stripes of Vss interconnects in another side, such as sides 501 and 601.

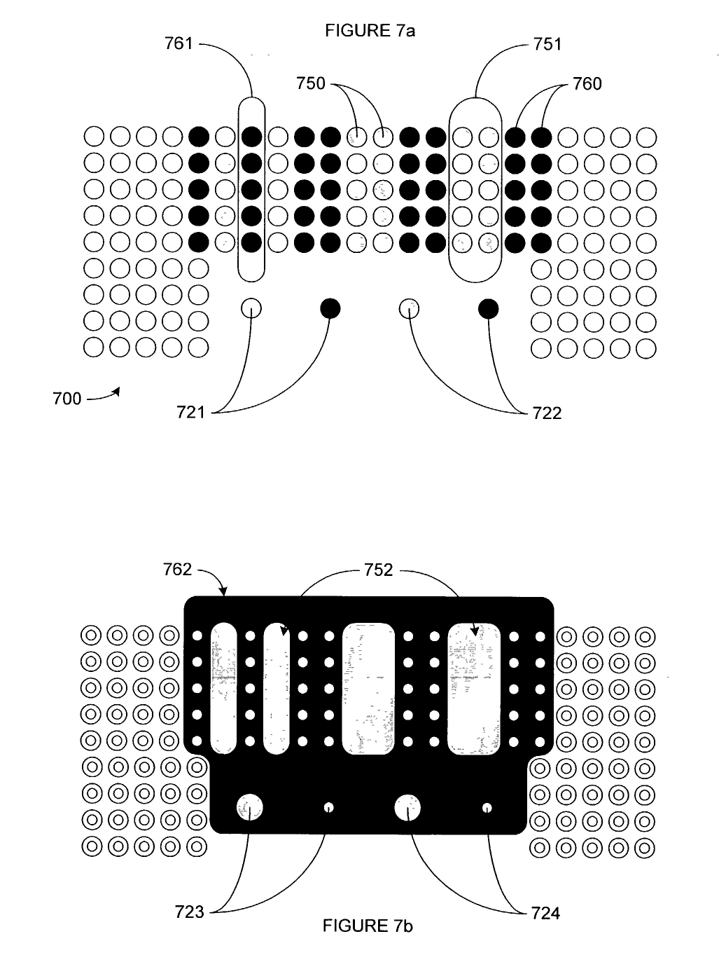

FIGS. 7a and 7b depict a portion of a pinout for a semiconductor device and the layout of corresponding conductors on a PCB in an embodiment in which through-hole technology is used to mount a semiconductor device to a PCB, as in the case of a semiconductor device using a pin grid array (PGA) package. Referring to FIG. 7a, pinout portion 700, in a manner corresponding to previously described embodiments, has Vss interconnects 750 and Vcc interconnects 760 arranged in stripes, such as Vss stripe 751 and Vcc stripe 761. In support of filtering components (not shown), interconnect pairs 721 and 722 are positioned near to pinout portion 700, and provide locations at which filtering components may be installed and thereby connected to Vss and Vcc.

Referring to FIG. 7b, the striped arrangement of Vss and Vcc interconnects, 750 and 760, of pinout portion 700 results in a corresponding layout of through-holes in a PCB that permits the conductive material on a layer of that PCB that forms Vss traces 752 to be laid out in a manner that causes relatively fewer breaks in continuity of the conductive material that forms Vcc plane 762 on that same layer. As can be seen, the resulting layout of plane 762 has wider pathways of conductive material formed all the way through pinout portion 700, and although not specifically shown, those skilled in the art of PCB design will readily recognize that a similar layout of a Vss plane is allowed for on another layer of the PCB. This in turn, provides a lower resistance pathway in both the Vcc plane 762 and the corresponding Vss plane for the flow of current between a semiconductor device using pinout portion 700 and both the filtering devices making use of interconnect pairs 721 and 722 (and corresponding pads and through-hole connections at locations 723 and 724), and a power source (not shown) on the side of pinout portion 700 opposite interconnect pairs 721 and 722.

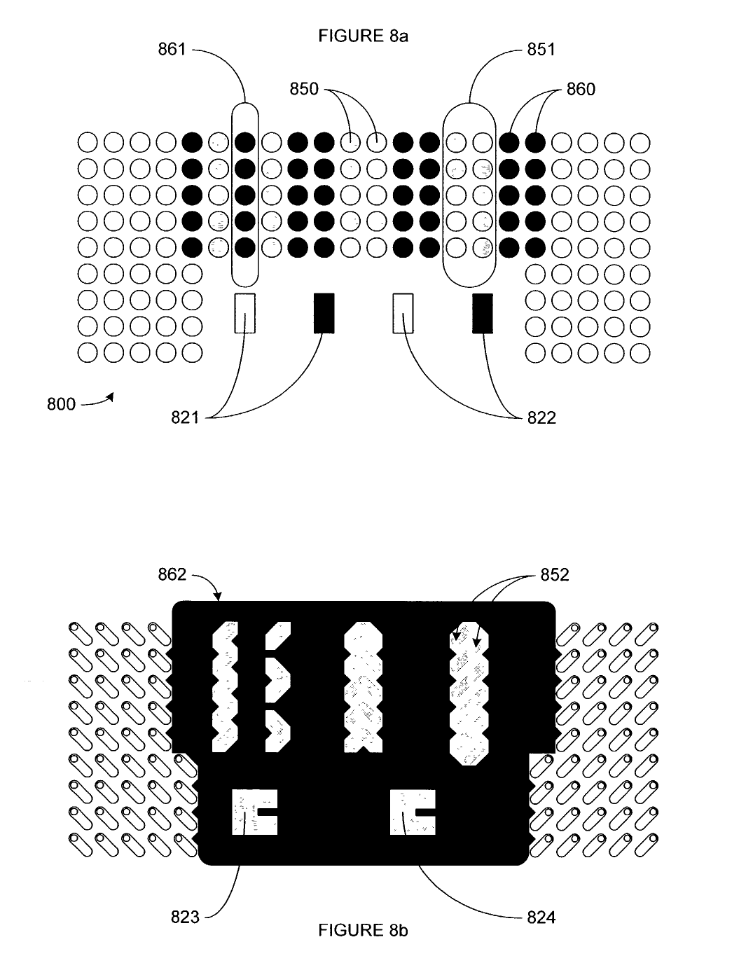

FIGS. 8a and 8b depict a portion of a pinout for a semiconductor device and the layout of corresponding conductors on a PCB in another embodiment in which surface mount technology is used to mount a semiconductor device to a PCB, as in the case of a semiconductor device using a ball grid array (BGA) package. Referring to FIG. 8a, pinout portion 800 is largely identical to pinout portion 700 of FIG. 7a, having Vss interconnects 850 and Vcc interconnects 860 arranged in stripes, such as Vss stripe 851 and Vcc stripe 861. In support of filtering components (not shown), interconnect pairs 821 and 822 are positioned near to pinout portion 800, and provide locations at which filtering components may be installed and thereby connected to Vss and Vcc. However, unlike pinout portion 700, pinout portion 800 does indicate the wider pads more common to surface mount capacitors used perform power filtering.

Referring to FIG. 8b, the conductive material on a surface of a PCB is laid out in a manner that those skilled in the art of PCB design will recognize as providing locations for soldering pads that are conductively connected to vias penetrating between the surface and other layers of the PCB. The striped arrangement of Vss and Vcc interconnects, 850 and 860, of pinout portion 800 results in a corresponding layout of Vss traces 852 on this surface that allows the vias to arranged in a manner that causes relatively fewer breaks in continuity of the conductive material that forms Vcc plane 862 to which interconnects of a semiconductor device using pinout portion 800 will direct attach. Various possible examples of layout for Vss traces 852 are shown corresponding to each of the stripes of Vss interconnects 850 of pinout 800. As can be seen, the arrangement of Vss interconnects 850 into stripes allows corresponding Vss traces 852 to be laid out so as to require only a single via for at least adjacent pairs of Vss interconnects 850, thereby reducing the number of vias penetrating Vss plane 862.

As can be seen, the resulting layout of plane 862 has wider pathways of conductive material formed all the way through pinout portion 800, and although not specifically shown, those skilled in the art of PCB design will readily recognize that a similar layout of a Vss plane is allowed for on another layer of the PCB. Just as in the case of the embodiment of FIGS. 7a and 7b, this in turn, provides a lower resistance pathway in both the Vcc plane 862 and the corresponding Vss plane for the flow of current between a semiconductor device using pinout portion 800 and both the filtering devices making use of interconnect pairs 821 and 822 (and corresponding pads and through-hole connections at locations 823 and 824), and a power source (not shown) on the side of pinout portion 800 opposite interconnect pairs 821 and 822.

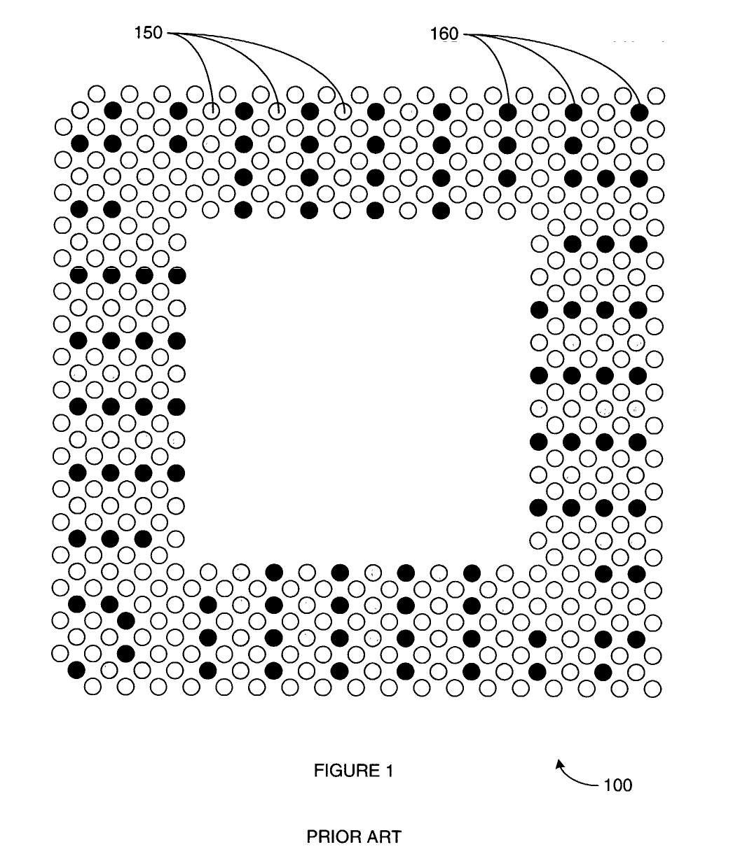

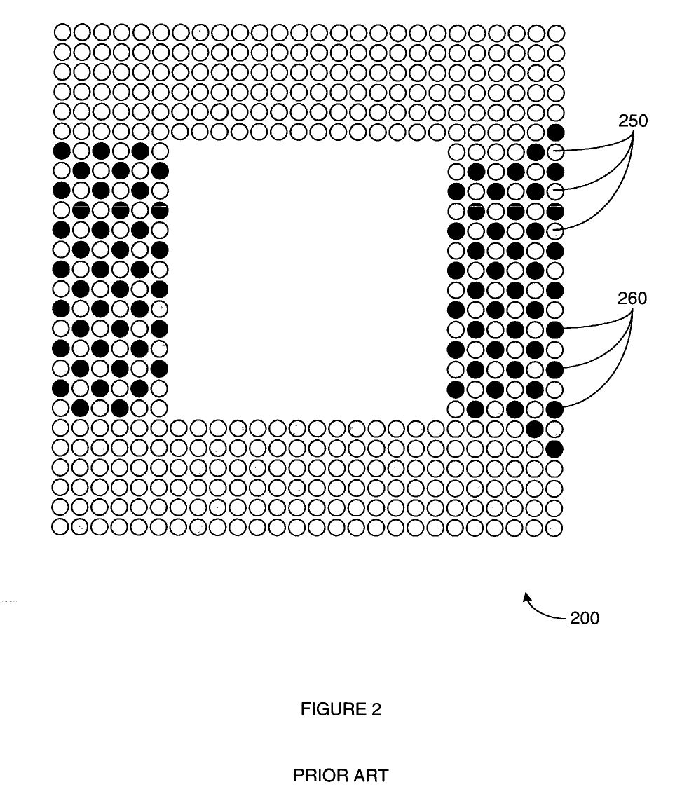

Referring variously to the embodiments depicted in FIGS. 1 through 8, the number of stripes of Vss and/or Vcc interconnects, the width(s) of those stripes, and/or the exact layout of traces and/or planes connecting to the interconnects making up those stripes may be arrayed to control or achieve desired inductance characteristics. In some embodiments, the number and/or width of stripes may be chosen to make use of inductance characteristics of the particular type of interconnect used to make up a given pinout. Inductance characteristics that are more desirable than those often encountered with the interspersing of Vcc and/or Vss interconnects may thereby be achieved. Alternatively, in other embodiments, the opportunity for wider traces of conductive material and/or planes of conductive material penetrated with fewer holes may be used to achieve desired inductance characteristics among the layers of conductive material of a PCB.

The teachings herein have been exemplified in conjunction with the preferred embodiment. Numerous alternatives, modifications, variations and uses will be apparent to those skilled in the art in light of the foregoing description. It will be understood by those skilled in the art that the invention as hereinafter claimed may be practiced in support of a wide variety of semiconductor devices using a wide variety of packages including, but not limited to, pin grid array and ball grid array. Also, although the example embodiments provided depict pinouts in which an open center location exists, it will be readily understood that the invention as hereinafter claimed may also be practiced in the support of semiconductor devices with pinouts that do not leave an open center location.

What is claimed is:

1. A semiconductor device comprising:
a package; and
a plurality of interconnects attached in a grid-like pinout to a first face of the package of the semiconductor device, wherein a first subset of the plurality of interconnects is connectable to a first power supply voltage, a second subset of the plurality of interconnects is connectable to a second power supply voltage, and wherein the interconnects of the first and second subset are arrayed into alternating adjacent parallel stripes of interconnects.

2. The semiconductor device of claim 1, wherein each of the alternating parallel stripes terminates at one end at a first edge of the first face of the package.

3. The semiconductor device of claim 2, wherein the alternating parallel stripes are oriented perpendicular to the first edge of the first face.

4. The semiconductor device of claim 1, wherein the grid-like pinout has an unpopulated center in which there are no interconnects.

5. The semiconductor device of claim 4, wherein at least one of the alternating parallel stripes terminates at one end at an edge of the first face of the package and terminates at the other end at an edge of the unpopulated center.

6. The semiconductor device of claim 4, wherein at least one of the alternating parallel stripes terminates at one end at an edge of the first face of the package and the other end forms a portion of an edge of the unpopulated center.

7. The semiconductor device of claim 1, wherein a third subset of the plurality of interconnects is connectable to the first power supply voltage and are among a fourth subset of the plurality of interconnects that is not connectable to a power supply voltage.

8. The semiconductor device of claim 1, wherein the plurality of interconnects are solderable to the surface of a PCB to mount the package to the surface of the PCB.

9. The semiconductor device of claim 1, wherein the plurality of interconnects are insertable through holes formed in a PCB to mount the package to the PCB.

10. A PCB comprising:
a first layer of conductive material;
a first location on a surface of the PCB to mount a semiconductor device having a package with interconnects arrayed in a grid-like pinout on a first surface of the package, the first location having a first edge;
a power source mounted to the PCB at a second location adjacent to the first edge of the first location;
a plane formed in the first layer of conductive material bridging the first and second locations, connected to a first power supply voltage provided by thee power source, and shaped to form parallel stripes of conductive material to connect to corresponding stripes of interconnects on the first surface of the package of a semiconductor device; and
a plurality of traces formed in the first layer of conductive material, and dispersed between the parallel stripes of the conductive material of the plane of conductive material.

11. The PCB of claim 10, wherein the plane of conductive material and the plurality of traces of conductive material each connects to a plurality of holes formed through the PCB to permit the mounting of a semiconductor device using through-hole technology.

12. The PCB of claim 10, wherein the plane of conductive material and the plurality of traces of conductive material are shaped to form locations for solder pads on the surface of the PCB to permit the mounting of a semiconductor device using surface mount technology.

13. The PCB of claim 10, further comprising a socket mounted to the PCB within the first location.

14. The PCB of claim 10, wherein each of the parallel stripes terminates at one end at the first edge of the first location.

15. The PCB of claim 14, wherein the parallel stripes of conductive material formed by the plane of conductive material are oriented perpendicular to the first edge of the first location.

16. The PCB of claim 10, wherein the layout of the parallel stripes of the plane of conductive material and the plurality of traces of conductive material are shaped to support the mounting of at least one filtering device within an unpopulated center of the grid-like pinout of a package of a semiconductor device.

17. The PCB of claim 16, wherein at least one of the parallel stripes of the plane terminates at one end at the first edge of the first location and terminates at the other end at an edge of where the unpopulated center of the grid-like pinout of the package overlies the PCB when semiconductor devices is mounted to the PCB.

18. The PCB of claim 16, wherein at least one of the parallel stripes of the plane terminates at one end at the first edge of the first location and the other end follows at least a portion of an edge where the unpopulated center of the grid-like pinout of the package overlies the PCB when semiconductor devices is mounted to the PCB.

19. A method comprising placing interconnects on a first face of a package of a semiconductor device in a grid-like pinout such that a first subset of the interconnects connectable to a first power supply voltage and a second subset of the interconnects connectable to a second power supply voltage so as to create alternating parallel stripes comprised of interconnects from the first and second subsets.

20. The method of claim 19, wherein each of the alternating parallel stripes terminates at one end at a first edge of the first face of the package.

21. The method of claim 20, wherein the alternating parallel stripes terminates are oriented perpendicular to the first edge of the first face of the package.

22. The method of claim 19, wherein the grid-like pinout has an unpopulated center in which there are no interconnects.

23. The method of claim 22, wherein at least one of the alternating parallel stripes terminates at one end at an edge of the first face of the package and terminates at the other end at an edge of the unpopulated center.

24. The method of claim 22, wherein at least one of the alternating parallel stripes terminates at one end at an edge of the first face of the package and the other end forms a portion of an edge of the unpopulated center.

25. The method of claim 19, wherein a third subset of the plurality of interconnects is connectable to the first power supply voltage and are among a fourth subset of the plurality of interconnects that is not connectable to a power supply voltage.
